(19) United States
(12) Patent Application Publication
(10) Pub. No.: US 2025/0133881 A1
(43) Pub. Date: Apr. 24, 2025

(54) DISPLAY PANEL AND DISPLAY DEVICE

(71) Applicants: Hefei Visionox Technology Co., Ltd., Hefei (CN); KUNSHAN GO-VISIONOX OPTO-ELECTRONICS CO., LTD., Kunshan (CN)

(72) Inventors: Xuejing ZHU, Hefei (CN); Xiaoxi SUN, Hefei (CN); Mingxing LIU, Hefei (CN)

(73) Assignees: Hefei Visionox Technology Co., Ltd., Hefei (CN); KUNSHAN GO-VISIONOX OPTO-ELECTRONICS CO., LTD., Kunshan (CN)

(21) Appl. No.: 18/757,633

(22) Filed: Jun. 28, 2024

(30) Foreign Application Priority Data
Oct. 20, 2023 (CN) 202311372030.0

(51) Int. Cl. H01L 33/54; H01L 25/075; H01L 33/38; H01L 33/62

(52) U.S. Cl. CPC H10H 20/853; H01L 25/0753; H10H 20/8312; H10H 20/857

(57) ABSTRACT

A display panel and a display device. The display panel includes: a substrate; an insulating structure disposed on the substrate and located in a display region and a first transition region; a partition structure disposed on the insulating structure and defining a first opening and a second opening corresponding to the first transition region and a hole region; a light emitting element disposed in the first opening on the insulating structure and located in the display region; and a first encapsulation layer located in the first transition region and covering the insulating structure.

### CROSS-REFERENCE TO RELATED APPLICATIONS

This application claims priority to Chinese patent application No. 2023113720300, filed on Oct. 20, 2023, the content of which is hereby incorporated by reference in its entirety.

### TECHNICAL FIELD

The present disclosure relates to the field of display technologies, and in particular, to a display panel and a display device.

### BACKGROUND

With the development of display technology, existing display devices are intentionally designed to achieve a high screen-to-body ratio, in order to enable a full screen. A hole-punch screen is a design that can increase the screen-to-body ratio of a mobile phone. The hole-punch screen can be realized by providing s a hole-punch region used for receiving a camera on the display panel. Isolation posts, encapsulation structures, etc. are usually required to be mounted at an edge of the hole-punch region, resulting in a large frame width of the hole-punch region. The wider frame of the hole-punch region affects the visual effect.

### SUMMARY

According to a first aspect, embodiments of the present disclosure provide a display panel having a hole region, a display region at least partially surrounding the hole region, and a first transition region located between the display region and the hole region. The display panel includes: a substrate; an insulating structure disposed on the substrate and located in the display region and the first transition region; a partition structure disposed on the insulating structure and defining a first opening and a second opening corresponding to the first transition region and the hole region; a light emitting element disposed in the first opening on the insulating structure and located in the display region; and a first encapsulation layer located in the first transition region and covering the insulating structure.

According to a second aspect, the embodiments of the present disclosure provide a display device, which includes the display panel as described in the first aspect.

In the display panel and the display device according to the embodiments of the present disclosure, by providing the partition structure, when the luminescent materials of the light emitting elements are evaporated, the luminescent materials of the adjacent light emitting element can be separated from each other, which is beneficial to the production of the light emitting element through pixel patterning technology, and eliminates the need for fine metal mask (FMM). Furthermore, by arranging the partition structure around the first transition region, when the luminescent materials of the light emitting elements are evaporated, the luminescent materials can be separated from each other, so that no luminescent material is provided in the first transition region. In this way, in the first transition region, no luminescent material is provided between the first encapsulation layer and the insulating structure, that is, no luminescent material is provided on the side of the first encapsulation layer adjacent to the substrate, which can increase the effective encapsulation area of the first encapsulation layer. Therefore, on the premise of achieving the same encapsulation effect, the present disclosure can reduce the width of the first transition region (i.e., the frame of the hole-punch region), which is beneficial to improve the visual effect.

These and other objects, advantages, purposes and features will become apparent upon review of the following specification in conjunction with the drawings.

### BRIEF DESCRIPTION OF THE DRAWINGS

In order to more clearly illustrate the technical solutions in the embodiments or the exemplary embodiments of the present disclosure, the drawings needed to be used in the description of the embodiments or the exemplary embodiments will be briefly introduced below. Apparently, the drawings described below merely illustrate some embodiments of the present disclosure, and other drawings can be derived by those of ordinary skill in the art without any creative effort.

FIG. 1 is a cross-sectional view of a display panel in the related art.

FIG. 2 is a top view of a display panel according to an embodiment of the present disclosure.

FIG. 3 is a partial enlarged view of the display panel shown in FIG. 2.

FIG. 4A is a cross-sectional view of the display panel shown in FIG. 2.

FIG. 4B is another cross-sectional view of the display panel shown in FIG. 2.

FIG. 5 is a yet another cross-sectional view of the display panel shown in FIG. 2.

FIG. 6 is a still further cross-sectional view of the display panel shown in FIG. 2.

FIG. 7 is a still further cross-sectional view of the display panel shown in FIG. 2.

FIG. 8 is a still further cross-sectional view of the display panel shown in FIG. 2.

FIG. 9 is a still further cross-sectional view of the display panel shown in FIG. 2.

FIG. 10 is a still further cross-sectional view of the display panel shown in FIG. 2.

FIG. 11 is a still further cross-sectional view of the display panel shown in FIG. 2.

FIG. 12 is a partial cross-sectional view of the display panel shown in FIG. 2.

FIG. 13 is a schematic view of a display device according to an embodiment of the present disclosure.

### ILLUSTRATION FOR REFERENCE NUMERALS

2. luminescent material; 3. first inorganic encapsulation layer; 4. organic encapsulation layer; 5. second inorganic encapsulation layer; 6. isolating column; 7. pixel definition layer; 1. display device; 10. display panel; 10a, hole region; 10b, display region; 10c, first transition region; 10d, second transition region; 11. substrate; 111. base; 112. blocking layer; 12. insulating structure; 12a, trench; 12b, first groove; 12c, overflow groove; 121, pixel definition layer; 122, gate insulating layer; 123, capacitor insulating layer; 124, interlayer dielectric layer; 13, partition structure; 13a, first opening; 13b, second opening; 14, light emitting element; 151, first encapsulation layer; 152, second encapsulation layer; 153, sub-encapsulation part; 16, buffer layer; 17, first planarization layer; 18, bank; 18a, second groove; 181, bank bottom; 1811, first section; 1812, second section; 1813, third section; 182, bank body; 183, bank top.

### DETAILED DESCRIPTION

In order to facilitate understanding of the present disclosure, the present disclosure will be described more fully below with reference to the relevant drawings. Preferred embodiments of the present disclosure are shown in the accompanying drawings. However, the present disclosure may be implemented in many different forms and is not limited to the embodiments described herein. Rather, these embodiments are provided so that a thorough understanding of the disclosure of the present disclosure will be provided.

It should be understood that although the terms “first”, “second”, etc. may be used herein to describe various elements, the terms do not imply any order, quantity, or importance, but are merely used to distinguish different components. These terms are only used to distinguish one element from another element. For example, a first element may be referred to as a second element, and similarly, a second element may be referred to as a first element, without departing from the scope of the present disclosure. Words such as “include” or “comprises” mean that the elements or items modified by the words include elements or items listed after the word and their equivalents, without excluding other elements or items.

Unless otherwise defined, all technical and scientific terms used herein have the same meaning as commonly understood by one of ordinary skill in the technical field to which the present disclosure belongs. The terms used herein in the description of the present disclosure is for the purpose of describing specific embodiments only and is not intended to limit the present disclosure. As used herein, the term “and/or” includes any and all combinations of one or more of the associated listed items.

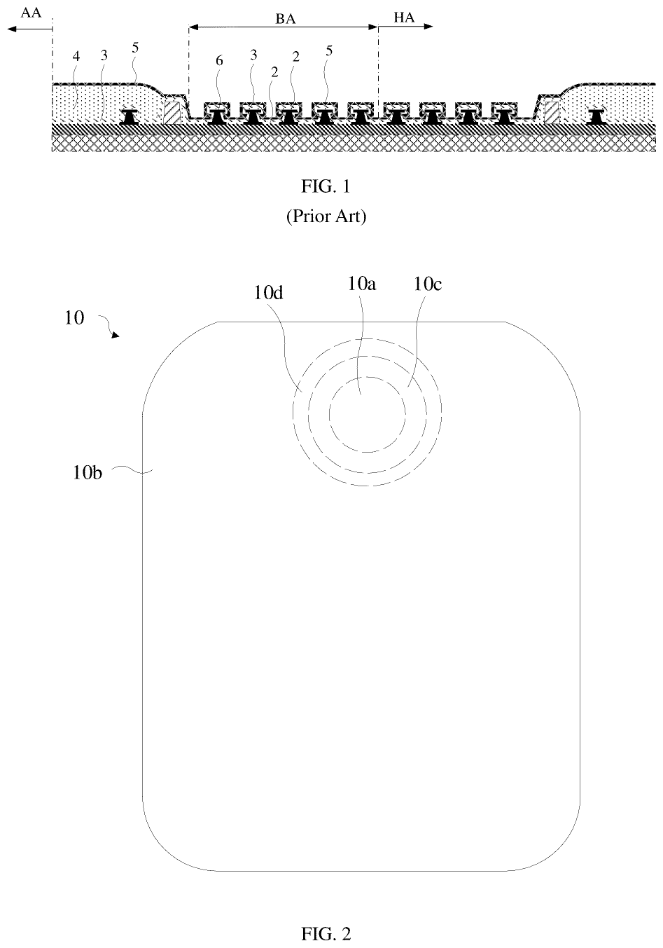

Referring to FIG. 1, in the related art, during the process of manufacturing a display panel, the structure in a hole-punch region HA usually needs to be cut off for receiving a camera. In order to prevent external water and oxygen from entering a display region AA of the display panel via the hole-punch region HA, it is usually necessary to provide isolating columns 6 in a frame region BA. Furthermore, in order to ensure the reliability of the package, it is usually necessary to provide five or more isolating columns 6, which results a large width of the frame region BA (the width of the frame region BA is usually greater than 100 μm). In this way, on the one hand, the wider frame region BA causes a black frame to appear around the camera, which affects the visual effect; on the other hand, the wider frame region BA causes the display region AA to be reduced, which reduces the effective display area.

Specifically, a light emitting element in the display region AA is packaged by a first inorganic encapsulation layer 3, an organic encapsulation layer 4, and a second inorganic encapsulation layer 5 that are stacked up. The frame region BA is packaged by the first inorganic encapsulation layer 3 and the second inorganic encapsulation layer 5.

The inventor has found through research that when manufacturing the light emitting element, the luminescent material 2 will cover the frame region BA. Specifically, the luminescent material 2 covers a surface of the pixel definition layer 7 and the top surfaces of the isolating columns 6. In this way, after the first inorganic encapsulation layer 3 covers the frame region BA, only the first inorganic encapsulation layer 3 on the sidewalls of the isolating columns 6 can enable an effective encapsulation. Since water and oxygen can diffuse along the luminescent material 2 on the surface of the pixel definition layer 7 and the luminescent material 2 on the top surfaces of the isolating columns 6, the first inorganic encapsulation layer 3 on the top surfaces of the isolating columns 6 and the surface of the pixel definition layer 7 achieves an invalid package. In this case, in order to improve the encapsulation reliability, a larger number of isolating columns 6 need to be provided, resulting in a large width of the frame region BA.

According to the present disclosure, a partition structure is utilized to separate adjacent light emitting elements. The partition structure is provided around a first transition region (or referred to as the frame region described above). In this way, when the luminescent materials of the light emitting elements are evaporated, the luminescent material can be separated from each other, so that no luminescent material is provided in the first transition region. As such, in the first transition region, no luminescent material is provided between the first encapsulation layer and an insulating structure. That is, no luminescent material is provided on a side of the first encapsulation layer adjacent to the substrate, which can increase the effective encapsulation area of the first encapsulation layer. Therefore, compared to the related art, on the premise of achieving the same encapsulation effect, the present disclosure can reduce the width of the first transition region (i.e., the width of the frame of the hole-punch region), which is beneficial to improve visual effects.

In a first aspect, referring to FIGS. 2, 3, 4A, and 12, an embodiment of the present disclosure provides a display panel 10. The display panel 10 may be an organic light emitting diode (OLED) 10, or a quantum dot light emitting diode (QLED) 10.

The display panel 10 has a hole region 10a, a display region 10b at least partially surrounding the hole region 10a, and a first transition region 10c located between the display region 10b and the hole region 10a.

The display panel 10 includes a substrate 11, an insulating structure 12, a partition structure 13, a light emitting element 14, and a first encapsulation layer 151. The insulating structure 12 is disposed on the substrate 11 and is located in the display region 10b and the first transition region 10c. The partition structure 13 is disposed on the insulating structure 12 and defines a first opening 13a and a second opening 13b corresponding to the first transition region 10c and the hole region 10a. The light emitting element 14 is disposed on the insulating structure 12 and located in the display region 10b. The light emitting element 14 is also disposed in the first opening 13a. The first encapsulation layer 151 is located in the first transition region 10c and covers a surface of the insulating structure 12. That is, in the first transition region 10c, the first encapsulation layer 151 is in direct contact with the insulating structure 12.

In the embodiments of the present disclosure, the partition structure 13 refers to a structure that can partition the luminescent materials of adjacent light emitting elements 14 when the luminescent materials of the light emitting elements 14 are evaporated. By providing the partition structure 13, when the luminescent materials of the light emitting elements 14 are evaporated, the luminescent materials of the adjacent light emitting elements 14 can be separated from each other, which is beneficial to the production of the light emitting element 14 through pixel patterning technology without the need for fine metal mask (FMM). In an embodiment, the partition structure 13 may be a single-layer structure, and in another embodiment, the partition structure 13 may also be a stacked structure.

It should be noted that the first encapsulation layer 151 is an inorganic film layer. In an embodiment of the present disclosure, the display panel 10 further includes a second encapsulation layer 152 and sub-encapsulation parts 153. One light emitting element 14 is packaged by a corresponding sub-encapsulation parts 153. The second encapsulation layer 152 is an organic film layer. The second encapsulation layer 152 covers all sub-encapsulation parts 153. The first encapsulation layer 151 covers the second encapsulation layer 152. In addition, the first encapsulation layer 151 also extends to cover the first transition region 10c.

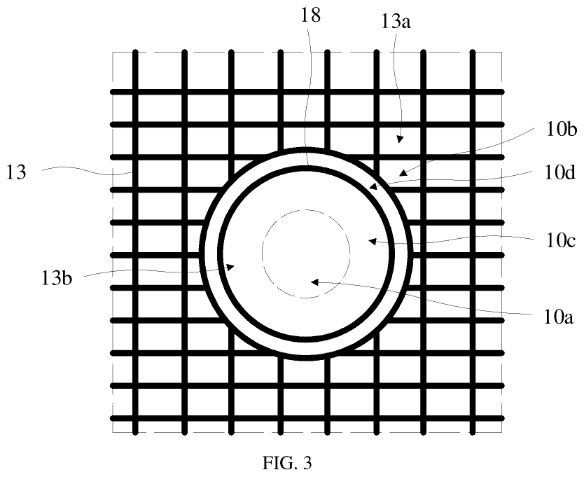

In an embodiment of the present disclosure, as shown in FIGS. 2 and 3, the display region 10b is located around the hole region 10a, and the first transition region 10c is also located around the hole region 10a. In this way, when the luminescent materials of the light emitting elements 14 are evaporated, the partition structure 13 can separate the luminescent materials from each other, that is, the luminescent material in the first transition region 10c and the luminescent material in the display region 10b are separated from each other. In this way, in the subsequent processes, the luminescent material in the first transition region 10c can be removed, so that there is no luminescent material in the first transition region 10c. In this way, in the first transition region 10c, no luminescent material is formed between the first encapsulation layer 151 and the insulating structure 12, that is, no luminescent material is formed on the side of the first encapsulation layer 151 adjacent to the substrate 11. When the first encapsulation layer 151 covers the first transition region 10c, the region covered by the first encapsulation layer 151 can be effectively packaged, thereby increasing the effective encapsulation area of the first encapsulation layer 151. Therefore, on the premise of achieving the same encapsulation effect, compared with the related art, the aforementioned embodiment can reduce the width of the first transition region 10c (i.e., the frame region BA as described above). As such, on the one hand, the black edges caused by the wider first transition region 10c can be alleviated, which is beneficial to improve the visual effect; on the other hand, the area of the display region 10b can be increased, which can improve the display effect of the display panel 10.

In an embodiment, the insulating structure 12 includes a first inorganic layer, and the first encapsulation layer 151 covers the surface of the first inorganic layer in the first transition region 10c.

In this way, in the first transition region 10c, the first encapsulation layer 151 is in direct contact with the inorganic film layer, so that external water and oxygen are not easily diffused toward the display region 10b along the boundary between the first encapsulation layer 151 and the pixel definition layer 121. It is beneficial to further improve the encapsulation reliability of the first encapsulation layer 151 in the first transition region 10c.

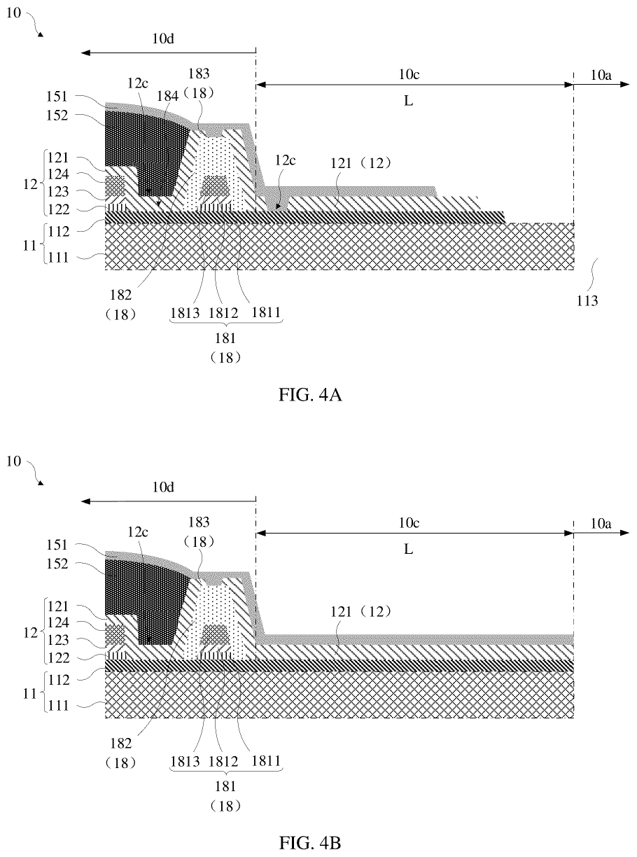

In an embodiment, referring to FIGS. 4A, 4B, 5, 6 and 7, the insulating structure 12 includes a pixel definition layer 121. The pixel definition layer 121 is the first inorganic layer. For example, the pixel definition layer 121 is located in the display region 10b and the first transition region 10c. In the first transition region 10c, the first encapsulation layer 151 is in direct contact with the pixel definition layer 121.

In this way, in the first transition region 10c, the first encapsulation layer 151 is in direct contact with the pixel definition layer 121, so that external water and oxygen are not easily diffused toward the display region 10b along the boundary between the first encapsulation layer 151 and the pixel definition layer 121. It is beneficial to further improve the encapsulation reliability of the first encapsulation layer 151 in the first transition region 10c.

In an embodiment, the insulating structure 12 further includes a gate insulating layer 122, a capacitor insulating layer 123, and an interlayer dielectric layer 124. The gate insulating layer 122, the capacitor insulating layer 123, and the interlayer dielectric layer 124 are stacked between the substrate 11 and the first inorganic layer (e.g., the pixel definition layer 121) in a direction away from the substrate 11. Partial surface of at least one of the gate insulating layer 122, the capacitor insulating layer 123, and the interlayer dielectric layer 124 is covered by the first encapsulation layer 151.

That is, in the first transition region 10c, the first encapsulation layer 151 is in direct contact with at least one of the gate insulating layer 122, the capacitor insulating layer 123, and the interlayer dielectric layer 124.

In this way, it is beneficial to increase the encapsulation area of the first encapsulation layer 151, thereby optimizing the encapsulation paths of the first encapsulation layer 151, and improving the encapsulation reliability of the first encapsulation layer 151 in the first transition region 10c.

In an embodiment, the gate insulating layer 122, the capacitor insulating layer 123, and the interlayer dielectric layer 124 are inorganic film layers, respectively. In this way, in the first transition region 10c, the first encapsulation layer 151 is in direct contact with the inorganic film layer, so that external water and oxygen are not easily diffused toward the display region 10b along the boundary between the first encapsulation layer 151 and the insulating structure 12, which is beneficial to further improve the encapsulation reliability of the first encapsulation layer 151 in the first transition region 10c.

In an embodiment, as shown in FIG. 8, the display panel 10 further includes a buffer layer 16 disposed between the insulating structure 12 and the substrate 11. The first encapsulation layer 151 also covers a portion of the surface of the buffer layer 16.

That is, in the first transition region 10c, the first encapsulation layer 151 is also in direct contact with the portion of the buffer layer 16.

In this way, it is beneficial to increase the encapsulation area of the first encapsulation layer 151, thereby optimizing the encapsulation paths of the first encapsulation layer 151, and improving the encapsulation reliability of the first encapsulation layer 151 in the first transition region 10c.

In an embodiment, the buffer layer 16 is an inorganic film layer.

In this way, in the first transition region 10c, the first encapsulation layer 151 is in direct contact with the inorganic film layer, so that external water and oxygen are not easily diffused toward the display region 10b along the boundary between the first encapsulation layer 151 and the buffer layer 16, which is beneficial to further improve the encapsulation reliability of the first encapsulation layer 151 in the first transition region 10c.

In an embodiment, as shown in FIGS. 4A to 8, the substrate 11 includes a first region 113 corresponding to the hole region 10a. An orthographic projection of the insulating structure 12 onto the substrate 11 is spaced apart from the first region 113.

It should be understood that an edge of the first region 113 is a cutting position. As such, a certain distance is formed from the edge of the insulating structure 12 to the cutting position. When the first region 113 is cut to form the hole region 10a, the insulating structure 12 will not be cut, thereby avoiding cracks in the insulating structure 12.

In an embodiment, the substrate 11 includes a base 111 and a blocking layer 112 that are stacked. The blocking layer 112 is located between the base 111 and the insulating structure 12.

In an embodiment, an orthographic projection of the blocking layer 112 onto the base 111 is spaced apart from the first region 113. In this way, when the first region 113 is cut to form the hole region 10a, the blocking layer 112 will not be cut, thereby avoiding cracks in the blocking layer 112.

In an embodiment, edges of the substrate 11, the insulating structure 12, and the first encapsulation layer 151 adjacent to the hole region 10a are coplanar with one another. In an embodiment, referring to FIG. 4B, edges of the base 111, the blocking layer 112, the pixel definition layer 121, and the first encapsulation layer 151 adjacent to the hole region 10 a are coplanar with one another.

In an embodiment, the display panel 10 further includes a second transition region 10d provided between the display region 10b and the first transition region 10c. The second transition region 10d can connect the display region 10b to the first transition region 10c.

In an embodiment, as shown in FIGS. 4A and 4B, the display panel 10 further includes a bank 18 disposed on the substrate 11. The bank 18 is located between the display region 10b and the first transition region 10c, and surrounds the first transition region 10c. By providing the bank 18, the organic material in the display region 10b can be blocked to prevent the organic material from overflowing to the first transition region 10c.

In an embodiment, as shown in FIGS. 4A, 4B, 5, 6 and 7, the bank 18 includes a bank bottom 181, a bank body 182, and a bank top 183 that are stacked in a direction away from the substrate 11.

In an embodiment, the bank bottom 181 refers to the portion located at the bottom of the bank 18; the bank body 182 refers to the portion located in the middle of the bank 18; and the bank top 183 refers to the part located on the surface of the bank 18.

In an embodiment, as shown in FIGS. 4A, 4B, 5, 6 and 7, the bank top 183 and the pixel definition layer 121 are disposed on the same layer. It should also be understood that the bank top 183 is composed of a portion of the pixel definition layer 121.

In an embodiment, the bank body 182 is made of an organic material. In this way, the height of the bank 18 can be controlled by laminating the organic material. In an embodiment, the bank body 182 and a planarization layer (not shown) of the display region 10b are disposed on the same layer, that is, the bank body 182 is composed of a portion of the planarization layer.

In an embodiment, the bank bottom 181 and the interlayer dielectric layer 124 are disposed on the same layer. It should also be understood that the bottom of the bank 18 is composed of a portion of the interlayer dielectric layer 124.

In an embodiment, the bank bottom 181 includes a first section 1811, a second section 1812, and a third section 1813 that are stacked in a direction away from the substrate 11. The first section 1811 and the gate insulating layer 122 are disposed on the same layer. The second section 1812 and the capacitor insulating layer 123 are disposed on the same layer. The third section 1813 and the interlayer dielectric layer 124 are disposed on the same layer. It should also be understood that the bottom of the bank 18 is composed of the gate insulating layer 122, the capacitor insulating layer 123, and the interlayer dielectric layer 124.

It should be noted that the bank 18 can be formed by stacking various film layers on the substrate 11. The stacking method for forming the bank 18 and the specific configuration of the bank 18 are not limited to the embodiments of the present disclosure.

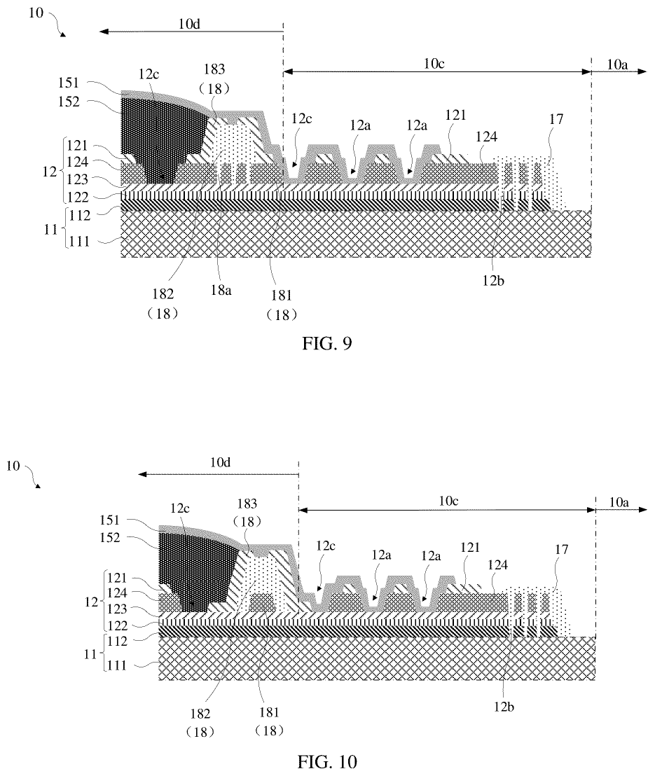

In an embodiment, as shown in FIG. 9, the bank 18 is provided with a second groove 18a extending through the bank bottom 181, and a portion of the bank body 182 is filled in the second groove 18a. As such, on the one hand, the extending of the cracks into the display region 10b can be prevented; on the other hand, the stress causing the extending of the cracks can be absorbed by the organic material, further preventing the extending of the cracks into the display region 10b.

In an embodiment, an anti-overflow structure is provided on the substrate 11. The anti-overflow structure is located on a side of the bank 18 adjacent to the display region 10b. In another embodiment, the anti-overflow structure is located on a side of the bank 18 adjacent to the first transition region 10c. By providing the anti-overflow structure, the organic material of the display region 10b can be prevented from overflowing to the first transition region 10c.

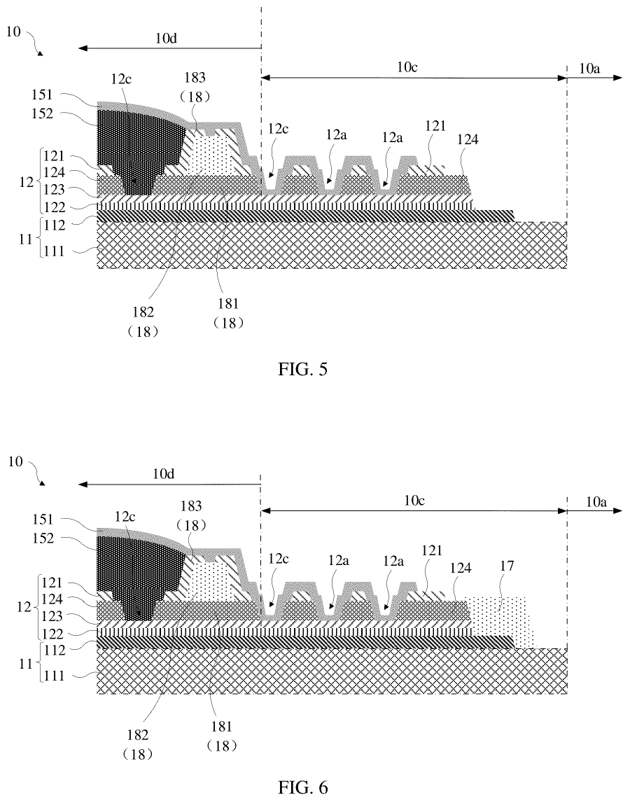

In an embodiment, the anti-overflow structure includes an overflow groove 12c. As shown in FIGS. 5, 6 and 7, the overflow groove 12c extends through the pixel definition layer 121 and the interlayer dielectric layer 124 in the thickness direction of the substrate 11. As such, when the organic material overflows, the organic material can overflow into the overflow groove 12c.

In this way, the overflow groove 12c is provided on the pixel definition layer 121 and the interlayer dielectric layer 124. Further, the bottom of the overflow groove 12c is located on the surface of the capacitor insulating layer 123, and the sidewall of the overflow groove 12c are located on the pixel definition layer 121 and the interlayer dielectric layer 124. Since the capacitor insulating layer 123, the pixel definition layer 121, and the interlayer dielectric layer 124 are all inorganic film layers, the groove wall of the overflow groove 12c is inorganic. When the organic material of the second encapsulation layer 152 overflows into the overflow groove 12c, an inorganic-organic-inorganic encapsulation structure can be formed in a region where the overflow groove 12c is located, thereby improving the encapsulation reliability of the region where the overflow groove 12c is located.

In an embodiment, as shown in FIGS. 4A and 4B, a recessed portion 184 is provided on the side of the bank 18 adjacent to the display region 10b. The first inorganic layer (for example, the pixel definition layer 121) covers the sidewall and the bottom wall of the recessed portion, and defines the overflow groove 12c.

In this way, the overflow groove 12c is formed by recessing the surface of the pixel definition layer 121. Therefore, the groove wall of the overflow groove 12c is also an inorganic groove wall. When the organic material of the second encapsulation layer 152 overflows to the overflow groove 12c, the inorganic-organic-inorganic encapsulation structure can be formed in the region where the overflow groove 12c is located, thereby improving the encapsulation reliability of the region where the overflow groove 12c is located.

In an embodiment, as shown in FIGS. 4A and 4B, a first distance L between the side of the first transition region 10c adjacent to the hole region 10a and the side of the first transition region 10c away from the hole region 10a have is defined. The first distance L satisfies: 30 μm≤L≤100 μm. For example, the first distance L may be 30 μm, 40 μm, 50 μm, 55 μm, 60 μm, 75 μm, 82 μm, 88 μm, 93 μm, 98 μm or 100 μm.

The first distance L is the width of the first transition region 10c as described above. By configuring the first distance L within the above range, the width of the first transition region 10c can be reduced. As such, on the one hand, the black edges caused by the wider first transition region 10c can be reduced, which is beneficial to improve the visual effect; on the other hand, the area of the display region 10b can be increased, which can improve the display effect of the display panel 10.

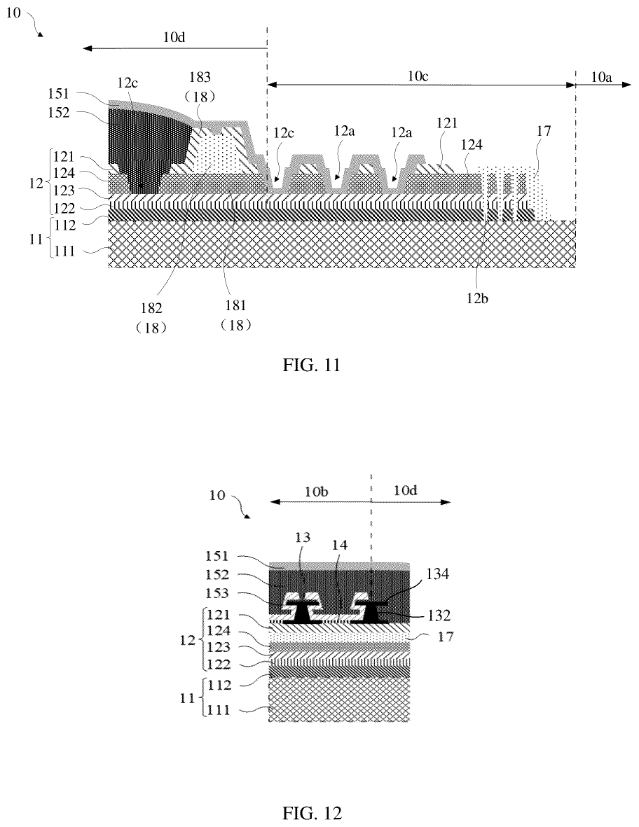

In an embodiment, as shown in FIGS. 5, 6, 7, 8, 9, 10 and 11, at least one trench 12a is provided in the first transition region 10c. The trench 12a extends through at least a part of the insulating structure 12 in the thickness direction of the substrate 11. The first encapsulation layer 151 also covers the groove wall of the at least one trench 12a.

By providing the trench 12a, on the one hand, the coverage area of the first encapsulation layer 151 in the first transition region 10c can be increased, thereby optimizing the encapsulation paths of the first encapsulation layer 151, improving the encapsulation reliability of the first encapsulation layer 151 in the first transition region 10c, and helping reducing the width of the first transition region 10c; on the other hand, the stress in the first transition region 10c can be reduced, which is beneficial to improve the reliability of the display panel 10.

In an embodiment, a plurality of trenches 12a are provided in the first transition region 10c. The plurality of trenches 12a are spaced apart in the radial direction of the hole region 10a. The first encapsulation layer 151 also covers the groove walls of the plurality of trenches. It should be understood that the radial direction of the hole region 10a refers to the direction from the hole region 10a to the display region 10b.

By providing the plurality of trenches 12a, the coverage area of the first encapsulation layer 151 in the first transition region 10c can be increased, thereby optimizing the encapsulation paths of the first encapsulation layer 151, improving the encapsulation reliability of the first encapsulation layer 151 in the first transition region 10c.

In an embodiment, the plurality of trenches 12a extend through the first inorganic layer (e.g., the pixel definition layer 121) and the interlayer dielectric layer 124 in the thickness direction of the substrate 11. In this way, the plurality of trenches 12a are provided on the pixel definition layer 121 and the interlayer dielectric layer 124. Further, the bottom of the trench 12a is located on the surface of the capacitor insulating layer 123, and the sidewalls of the trench 12a are located on the pixel definition layer 121 and the interlayer dielectric layer 124 respectively. Since the capacitor insulating layer 123, the pixel definition layer 121, and the interlayer dielectric layer 124 are all inorganic, the groove wall of the trench 12a is an inorganic groove wall. When the first encapsulation layer 151 covers the groove wall of the trench 12a, the first encapsulation layer 151 is in direct contact with the inorganic trench wall, and the external water and oxygen are not easily diffused toward the display region 10b along the boundary between the first encapsulation layer 151 and the inorganic groove wall, which is beneficial to further improve the encapsulation reliability of the first encapsulation layer 151 in the first transition region 10c.

In an embodiment, an orthographic projection of the trench 12a onto the substrate 11 is shaped as a closed ring, that is, the trench 12a is an annular trench. For example, the trench 12a may be a circular annular groove, a rectangular annular groove, a triangular annular groove, or the like.

In an embodiment, as shown in FIGS. 8, 9, 10 and 11, at least one first groove 12b is further provided in the first transition region 10c. The at least one first groove 12b is located on the side of the trench 12a adjacent to the hole region 10a. The at least one first groove 12b extends through the insulating structure 12 in the thickness direction of the substrate 11. By providing the first groove 12b, the extending of cracks in the hole region 10a into the first transition region 10c can be prevented.

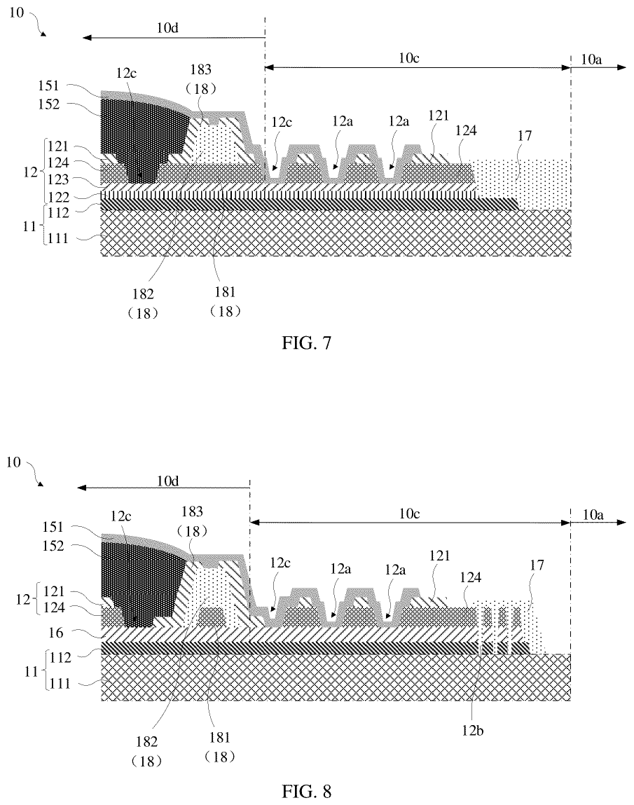

In an embodiment, as shown in FIGS. 6 and 7, the display panel 10 further includes a first planarization layer 17 disposed on the substrate 11. The first planarization layer 17 is located in the first transition region 10c. In an embodiment, the first planarization layer 17 is made of organic materials. In an embodiment, as shown in FIGS. 8, 9, 10 and 11, the first planarization layer 17 covers the insulating structure 12 in the first transition region 10c and is filled in the first groove 12b.

In this way, the stress causing the extending of the cracks can be absorbed by the first planarization layer 17, so that the extending of the crack into the first transition region 10c can be further prevented.

In an embodiment, an orthographic projection of the first planarization layer 17 onto the substrate 11 is spaced apart from the hole region 10a. With the above configuration, a certain distance is kept between the edge of the first planarization layer 17 and the cutting position. As such, when cutting the hole region 10a, the first planarization layer 17 will not be cut, thereby avoiding the defects caused by cutting the first planarization layer 17.

In another embodiment, as shown FIG. 7, the orthographic projection of the first planarization layer 17 onto the substrate 11 coincides with the edge of the hole region 10a. In this way, when cutting the hole region 10a, since the first planarization layer 17 is organic, the first planarization layer 17 can absorb the stress on the substrate 11 and alleviate the tendency of occurrence of cracks on the substrate 11. It should be understood that the first planarization layer 17 is organic. Therefore, when the first planarization layer 17 is cut, cracks will not occur in the first planarization layer 17.

In an embodiment, a plurality of first grooves 12b are provided in the first transition region 10c. The plurality of first grooves 12b are disposed at intervals in the radial direction of the hole region 10a. By providing the plurality of first grooves 12b, the ability to prevent the extending of cracks can be improved, and the reliability of the display panel 10 can be improved.

In an embodiment, as shown in FIG. 12, the display region 10b is also provided with the first planarization layer 17. The first planarization layer 17 is located between the pixel definition layer 121 and the interlayer dielectric layer 124.

In an embodiment, as shown in FIG. 12, the partition structure 13 includes a partition body 132 and a partition portion 134 that are stacked in the direction away from the substrate 11. An orthographic projection of the top surface of the partition body 132 onto the substrate 11 is located within an orthographic projection of the bottom surface of the partition portion 134 onto the substrate 11. In this way, an undercut structure can be formed on the partition structure 13, so that the luminescent materials of adjacent light emitting elements 14 can be partitioned from each other.

In an embodiment, the partition body 132 includes a first metal layer (not labeled). The light emitting element 14 includes a first electrode (not labeled), a light-emitting portion (not labeled), and a second electrode (not labeled) that are stacked in the direction away from the substrate 11. The second electrode is electrically connected to the first metal layer.

It can be understood that the first electrode may be an anode and the second electrode may be a cathode. A pixel driving circuit is formed on the substrate 11. Both the first electrode and the second electrode are electrically connected to the pixel driving circuit. The light-emitting portion at least includes an emission layer (EML). In another embodiment, the light-emitting portion may further include at least one or more of a hole injection layer (HIL), a hole transport layer (HTL), an electron injection layer (EIL), an electron transport layer (ETL), a hole block layer 112 (HBL), and an electron block layer 112 (EBL). Alternatively, the light-emitting portion may also be a stacked light-emitting layer, that is, the light-emitting portion includes at least two light-emitting layers and a charge generation layer (CGL) located between adjacent light-emitting layers.

In an embodiment, the partition body 132 is made of at least one of metal and metal oxide. For example, the metal may be silver, copper, titanium, aluminum, etc. The metal oxide can be tin oxide, zinc oxide, cadmium oxide, indium oxide, indium tin oxide, zinc indium oxide, zinc gallium oxide, zinc aluminum oxide, titanium tantalum oxide, etc.

In an example, the partition body 132 includes the first metal layer (not labeled) and a second metal layer (not labeled) that are stacked in the direction away from the substrate 11. An outer contour of an orthographic projection of the first metal layer onto the substrate 11 is located around an outer contour of an orthographic projection of the second metal layer onto the substrate 11. The first metal layer and the second metal layer are sequentially stacked in the direction away from the substrate 11. In an embodiment, the first metal layer may be made of Mo, and the second metal layer may be made of Al.

In an embodiment, the partition portion 134 is made of metal. For example, the partition portion 134 is made of Ti. In this way, by providing three metal layers that are stacked, the resistance of the partition structure 13 can be reduced, thereby reducing the power consumption of the display panel 10.

In an embodiment, the cross-section of the partition structure 13 formed by the first metal layer, the second metal layer and the partition portion 134 may be I-shaped.

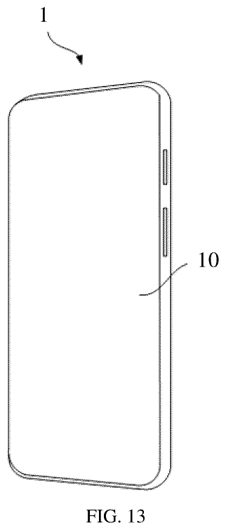

In a second aspect, referring to FIG. 13, an embodiment of the present disclosure provides a display device 1. The display device 1 includes the display panel 10 in any of the embodiments of the first aspect.

The display device 1 may be a notebook computer, a mobile phone, a wireless device, a personal digital assistant (PDA), a handheld or portable computer, a GPS receiver/navigator, a camera, an MP4 video player, a video camera, a game control console, a watch, a clock, a calculator, a television monitor, a flat panel display, a computer monitor, an automotive display (e.g., odometer displays, etc.), a navigator, a cockpit controller and/or a display, a display of a camera (e.g., a display of a rear-view camera in a vehicle), an electronic photo, an electronic billboards or signs, projectors, etc.

In the display device according to the embodiments of the present disclosure, when the luminescent materials of the light emitting elements 14 are evaporated, the partition structure 13 can isolate the luminescent materials, that is, the luminescent material in the first transition region 10c is separated from the luminescent material in the display region 10b. In this way, in subsequent processes, the luminescent material in the first transition region 10c can be removed, so that no luminescent material is provided in the first transition region 10c. In this way, in the first transition region 10c, no luminescent material is provided between the first encapsulation layer 151 and the insulating structure 12. That is, no luminescent material is provided on the side of the first encapsulation layer 151 adjacent to the substrate 11. When the first encapsulation layer 151 covers the first transition region 10c, the regions covered by the first encapsulation layer 151 can achieve effective encapsulation, thereby increasing the effective encapsulation area of the first encapsulation layer 151. Therefore, on the premise of achieving the same encapsulation effect, compared with the related art, the present disclosure can reduce the width of the first transition region 10c (i.e., thee frame region BA as described above). As such, on the one hand, the black edges caused by the wider first transition region 10c can reduced, which is beneficial to improving the visual effect; on the other hand, the area of the display region 10b can be increased, which can improve the display effect of the display panel 10.

When the terms “including”, “having”, and “comprising” are used herein, another component may also be added unless an expressly qualified term such as “only”, “consisting of” etc. is used. Unless mentioned to the contrary, the singular terms may include the plural forms, and shall not be construed as being one in number.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present disclosure.

The above-described embodiments are only several implementations of the present disclosure, and the descriptions are relatively specific and detailed, but they should not be construed as limiting the scope of the present disclosure. It should be understood by those of ordinary skill in the art that various variants and improvements can be made without departing from the concept of the present disclosure, and all fall within the protection scope of the present disclosure. Therefore, the patent protection of the present disclosure shall be subjected to the appended claims.

What is claimed is:

1. A display panel, having a hole region, a display region at least partially surrounding the hole region, and a first transition region located between the display region and the hole region, the display panel comprising:
a substrate;
an insulating structure disposed on the substrate and located in the display region and the first transition region;
a partition structure disposed on the insulating structure and defining a first opening and a second opening corresponding to the first transition region and the hole region;
a light emitting element disposed in the first opening on the insulating structure and located in the display region; and
a first encapsulation layer located in the first transition region and covering the insulating structure.

2. The display panel according to claim 1, wherein the partition structure comprises a first inorganic layer, the first encapsulation layer covers the first inorganic layer, the insulating structure comprises a pixel definition layer, and the pixel definition layer is the first inorganic layer.

3. The display panel according to claim 2, wherein the insulating structure further comprises a gate insulating layer, a capacitor insulating layer, and an interlayer dielectric layer that are stacked between the substrate and the first inorganic layer in a direction away from the substrate, the first encapsulation layer covering a partial surface of at least one of the gate insulating layer, the capacitor insulating layer, and the interlayer dielectric layer, the gate insulating layer, the capacitor insulating layer, and the interlayer dielectric layer being inorganic film layers.

4. The display panel according to claim 1, further comprising a buffer layer disposed between the insulating structure and the substrate, wherein the first encapsulation layer further covers a part of the buffer layer;
wherein the buffer layer is an inorganic film layer;
wherein the substrate has a first region corresponding to the hole region, and an orthographic projection of the insulating structure onto the substrate is spaced apart from the first region.

5. The display panel according to claim 1, wherein the first transition region is provided with at least one trench therein, each trench extends through at least a part of the insulating structure in a thickness direction of the substrate; and the first encapsulation layer further covers a groove wall of the at least one trench.

6. The display panel according to claim 5, wherein the at least one trench comprises a plurality of trenches, the plurality of trenches are spaced apart in a radial direction of the hole region, and the first encapsulation layer further covers groove walls of the plurality of trenches;
wherein each trench extends through the first inorganic layer and the interlayer dielectric layer in the thickness direction of the substrate;
wherein an orthographic projection of each trench onto the substrate is shaped as a closed ring.

7. The display panel according to claim 1, wherein the first transition region is provided with at least one first groove therein, the at least one first groove is located on a side of the trench adjacent to the hole region, and each first groove extends through the insulating structure in a thickness direction of the substrate.

8. The display panel according to claim 7, further comprising a first planarization layer disposed on the substrate, and the first planarization layer being located in the first transition region.

9. The display panel according to claim 8, wherein the first planarization layer covers the insulating structure in the first transition region and is filled in the at least one first groove;
wherein an orthographic projection of the first planarization layer onto the substrate is spaced apart from the hole region;
wherein the at least one first groove comprises a plurality of first grooves, and the plurality of first grooves are spaced apart in a radial direction of the hole region.

10. The display panel according to claim 3, further comprising a bank disposed on the substrate, wherein the bank is located between the display region and the first transition region, and surrounds the first transition region.

11. The display panel according to claim 10, wherein the bank comprises a bank bottom, a bank body, and a bank top that are stacked in a direction away from the substrate;
wherein the bank top and the pixel definition layer are disposed on the same layer.

12. The display panel according to claim 11, wherein the bank body is made of an organic material;
wherein the bank bottom and the interlayer dielectric layer are disposed on the same layer.

13. The display panel according to claim 12, wherein the bank bottom comprises a first section, a second section, and a third section that are stacked in the direction away from the substrate, the first section and the gate insulating layer are disposed on the same layer, the second section and the capacitor insulating layer are disposed on the same layer, and the third section and the interlayer dielectric layer are disposed on the same layer;
wherein the bank is provided with a second groove extending through the bank bottom, and a portion of the bank body is filled in the second groove.

14. The display panel according to claim 10, further comprising an anti-overflow structure provided on the substrate, wherein the anti-overflow structure is located on a side of the bank adjacent to the display region,
or the anti-overflow structure is located on a side of the bank adjacent to the first transition region.

15. The display panel according to claim 14, wherein the anti-overflow structure comprises an overflow groove extending through the pixel definition layer and the interlayer dielectric layer in a thickness direction of the substrate;
wherein a side of the bank adjacent to the display region is provided with a recessed portion, and the first inorganic layer covers a sidewall and a bottom wall of the recessed portion, and defines the overflow groove.

16. The display panel according to claim 1, wherein a side of the first transition region adjacent to the hole region and a side of the first transition region away from the hole region have a first distance L defined therebetween, and 30 μm≤L≤100 μm.

17. The display panel according to claim 1, wherein the substrate comprises a base and a blocking layer, the blocking layer is located between the base and the insulating structure, and an orthographic projection of the blocking layer onto the base is spaced apart from the hole region.

18. The display panel according to claim 1, wherein the partition structure comprises a partition body and a partition portion that are stacked in a direction away from the substrate, and an orthographic projection of a top surface of the partition body onto the substrate is located within an orthographic projection of a bottom surface of the partition portion onto the substrate.

19. The display panel according to claim 18, wherein the partition body comprises a first metal layer, the light emitting element comprises a first electrode, a light-emitting portion, and a second electrode that are stacked in the direction away from the substrate, and the second electrode is electrically connected to the first metal layer.

20. The display panel according to claim 19, wherein the partition body further comprises a second metal layer located on a side of the first metal layer adjacent to the substrate, and the blocking portion is made of metal.
